(19) United States
(12) Patent Application Publication
(10) Pub. No.: US 2023/0253226 A1
(43) Pub. Date: Aug. 10, 2023

(54) CHIP CARRIER

(71) Applicants: Po-Hsiang CHANG, Taoyuan City (TW); Sheng-Hung WANG, Taoyuan City (TW)

(72) Inventors: Po-Hsiang CHANG, Taoyuan City (TW); Sheng-Hung WANG, Taoyuan City (TW)

(21) Appl. No.: 18/094,428

(22) Filed: Jan. 9, 2023

(30) Foreign Application Priority Data
Jan. 13, 2022 (TW) 111101571

(51) Int. Cl. H01L 21/673; G01R 31/28

(52) U.S. Cl. CPC H01L 21/67333; G01R 31/2893

(57) ABSTRACT

The present invention provides a chip carrier that selectively carries a chip under test or a standard chip. The chip carrier comprises a body and a load board. The body defines a test area located on an upper surface of the body, and a first chip position is defined in the test area. The load board is detachably located in the test area, and a second chip position is defined in the load board. A standard chip is disposed within the second chip position. When the load board is located in the test area, the load board covers the first chip position and the chip under test is not disposed within the first chip position. When the chip under test is disposed within the first chip position, the load board is not located in the test area.

### CROSS REFERENCE TO RELATED APPLICATION

The present application claims priority to Taiwan patent application Serial No. 111101571 filed on Jan. 13, 2022 the entire content of which is incorporated by reference to this application.

### BACKGROUND OF THE INVENTION

### 1. Field of the Invention

The present invention pertains to a chip carrier, more specifically to a chip carrier that can be switched to carry a chip under test or to carry a standard chip.

### 2. Description of the Prior Art

After a chip is made, a series of tests are often required to ensure the quality of the production. Since different test items need to be performed in different stations, the chip also needs to be transported between the stations. For example, the chip is generally picked up by a suction nozzle. After the suction nozzle moves to a specific position of the next station, the chip is then released. However, person having ordinary skill in the art can understand that when more test items are required, moving the chips one by one will make the entire testing process very time-consuming. Especially when the size of the chip becomes smaller and smaller, repeatedly picking up and releasing the chip will increase the chance of damaging it.

In addition, assuming that the chip needs to undergo electrical testing, it will first be placed in a test position of a station, and then the electrode of the chip can be contacted by a probe for providing test signals. Besides, a special jig with a standard chip needs to be used during calibration, but the special jig may not be compatible with the original test position where the chip was placed, makes the calibration process more complicated. Therefore, the industry needs a new chip carrier that can improve efficiency in transporting chips and reduce contacting with the chips directly. In addition, the industry also needs a chip carrier that can quickly apply the standard chip to improve its versatility.

### SUMMARY OF THE INVENTION

The present invention provides a chip carrier which can reduce the repeated suction and release of the chip, thereby reducing the chance of the chip being damaged. In addition, the chip carrier can also be switched to carry a chip under test or to carry a standard chip so as to provide commonality of the chip carrier in multiple situations.

The present invention provides a chip carrier that selectively carries a chip under test or a standard chip. The chip carrier comprises a body and a load board. The body defines a test area located on an upper surface of the body, and a first chip position is defined in the test area. The load board is detachably located in the test area, and a second chip position is defined in the load board. A standard chip is disposed within the second chip position. When the load board is located in the test area, the load board covers the first chip position and the chip under test is not disposed within the first chip position. When the chip under test is disposed within the first chip position, the load board is not located in the test area.

In some embodiments, the load board defines a first surface and a second surface opposite to each other. The second chip position may be located on the first surface. When the load board is located in the test area, the second surface can contact the first chip position. Herein, a first electrode pad may also be provided on the first surface. The first electrode pad is connected to a protective conductor. The protective conductor can shield the standard chip in a vertical direction, and the standard chip is a light emitting chip in side-emission configuration. In addition, a conductive block may be disposed within the load board. The conductive block is exposed at the second chip position on the first surface and also exposed on the second surface. Furthermore, the protective conductor may be composed of a protective cantilever and an elastic block. The protective cantilever can shield the standard chip in a vertical direction, and the elastic block is located between the protective cantilever and the first surface and can absorb stress applied to the protective cantilever..

In some embodiments, a second electrode pad may be provided on the first surface. The second electrode pad is disposed within the second chip position and connected to the conductive block. The conductive block is disposed within the load board and exposed on the second surface. In addition, an extended electrode pad may also be provided on the first surface. The protective conductor is electrically connected to the first electrode pad and the extended electrode pad.

In some embodiments, the test area can be recessed into the upper surface, the load board is placed in the test area, and the body is made of conductive material. In addition, the load board may have a temperature control unit for controlling an ambient temperature around the second chip position. Furthermore, the body may have an identification pattern for identifying the chip carrier.

In summary, the chip carrier provided by the present invention has a detachable load board that can carry a standard chip. When the load board is located in the body, the combination of the body and the load board can be regarded as a standard part. When the load board is not located in the body, the body can carry a chip under test which can reduce the repeated suction and release of the chip, thereby reducing the chance of the chip being damaged.

### BRIEF DESCRIPTION OF THE APPTERMINALED DRAWINGS

FIG. 1 illustrates a three-dimensional schematic diagram of a chip carrier according to an embodiment of the present invention.

FIG. 2 illustrates an exploded view of the chip carrier according to an embodiment of the present invention.

FIG. 3 illustrates a three-dimensional schematic diagram of a load board according to an embodiment of the present invention.

FIG. 4 illustrates a three-dimensional schematic diagram of a chip carrier according to another embodiment of the present invention.

FIG. 5 illustrates an exploded view of the chip carrier according to another embodiment of the present invention.

FIG. 6 illustrates a three-dimensional schematic diagram of a load board according to another embodiment of the present invention.

FIG. 7 illustrates a three-dimensional schematic diagram of a chip carrier according to yet another embodiment of the present invention.

FIG. 8 illustrates an exploded view of the chip carrier according to yet another embodiment of the present invention.

FIG. 9 illustrates a three-dimensional schematic diagram of a load board according to yet another embodiment of the present invention.

FIG. 10 illustrates a three-dimensional schematic diagram of a chip carrier according to still another embodiment of the present invention.

FIG. 11 illustrates an exploded view of the chip carrier according to still another embodiment of the present invention.

FIG. 12 illustrates a three-dimensional schematic diagram of part of a load board according to still another embodiment of the present invention.

### DETAILED DESCRIPTION OF THE INVENTION

The features, targetions, and functions of the present invention are further disclosed below. However, it is only a few of the possible embodiments of the present invention, and the scope of the present invention is not limited thereto; that is, the equivalent changes and modifications done in accordance with the claims of the present invention will remain the subject of the present invention. Without departing from the spirit and scope of the invention, it should be considered as further enablement of the invention.

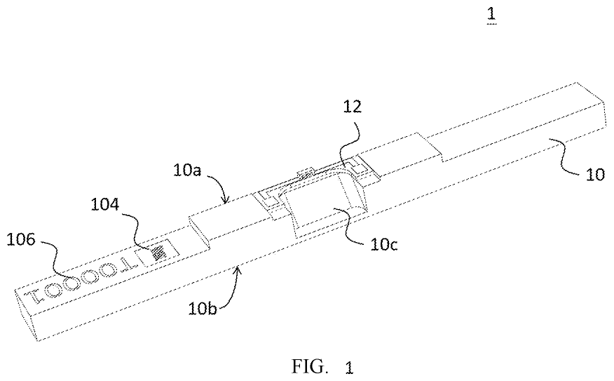

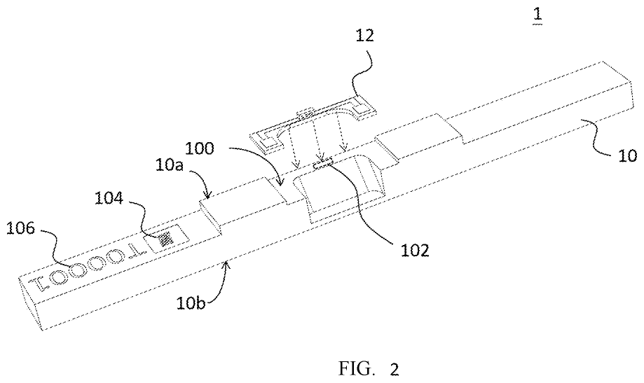

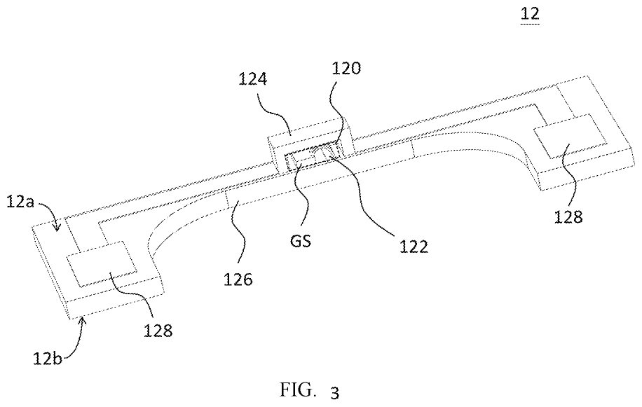

Please also refer to FIG. 1, FIG. 2 and FIG. 3. FIG. 1 illustrates a three-dimensional schematic diagram of a chip carrier according to an embodiment of the present invention. FIG. 2 illustrates an exploded view of the chip carrier according to an embodiment of the present invention. FIG. 3 illustrates a three-dimensional schematic diagram of a load board according to an embodiment of the present invention. As shown in the figures, the chip carrier 1 has a body 10 and a load board 12. The body 10 can be defined as having an upper surface 10a and a lower surface 10b on opposite sides. This embodiment does not limit that the upper surface 10a (or lower surface 10b) is an overall flat surface, and the upper surface 10a (or lower surface 10b) may have protrusions or recesses. For example, the upper surface 10a may refer to all surfaces of the body 10 facing upwardly, and the lower surface 10b may refer to all surfaces of the body 10 facing downwardly. In addition, the upper surface 10a can be defined as having a test area 100, which can be roughly located in the center of the upper surface 10a, and the test area 100 is recessed from the upper surface 10a to form a segment difference with the upper surface 10a. However, this embodiment does not limit the structure of the test area 100. For example, the test area 100 may not be recessed from the upper surface 10a but may be in the same plane as the upper surface 10a. In addition, this embodiment does not limit the shape of the test area 100. For example, since the figures shows that the body has an inclined plane 10c, so that the test area can have an irregular shape. In practice, as long person having ordinary skill in the art can distinguish an area from the upper surface 10a of the body that can accommodate or fit the load board 12, such area should belong to the scope of the test area 100 in this embodiment.

Assuming that the load board 12 has not yet been placed in the test area 100 of the body 10, it can be seen from FIG. 2 that the test area 100 of the body 10 should be a flat surface. In this embodiment, a position for placing a chip can be defined in the test area 100, such as a first chip position 102. Although FIG. 2 shows only one first chip position 102, this embodiment is not limited to FIG. 2. For example, multiple positions for placing chips can also be defined in the test area 100. The first chip position 102 refers to the position in the test area 100 where a chip under test (not shown in the FIG.) is scheduled to be placed, and each first chip position 102 is used to accommodate one corresponding chip under test. Because the test area 100 is not covered by the load board 12, the first chip position 102 in the test area 100 is not covered and the chip under test can be directly placed in the first chip position 102. It is worth mentioning that there is no default chip under test in the first chip position 102 in the test area 100. The chip under test can only be placed in the first chip position 102 when the test area 100 is not covered by the load board 12.

In practice, the body 10 can be made of conductive material, and the electrodes of the chip under test are electrically connected to the body 10. In this embodiment, the described chip under test can be a light emitting chip in side-emission configuration, and the chip under test can, at least, emit light toward the inclined surface 10c of the body 10. In one example, the two electrodes of the chip under test can be located on the top and bottom of the chip under test respectively. The electrode (e.g., cathode) on the bottom of the chip under test is electrically connected to a test equipment via the body 10, while the electrode (e.g., anode) on the top of the chip under test can be electrically connected to a probe of the test equipment. Therefore, even when the load board 12 of the chip carrier 1 is not placed in the body 10, electrical tests can still be performed directly on the chip under test disposed on the body 10 by the test equipment. For example, assuming that the test equipment is calibrated and can drive the chip under test to check its light-emitting characteristics. At this time, the chip under test can be directly placed in the first chip position 102 of the body 10 and driven by said test equipment to emit light. That is to say, without assembling load board 12 of chip carrier 1, the body 10 can independently carry the chip under test and can be used to perform tests.

On the other hand, if the test equipment needs to be calibrated, such as under development or awaiting calibration. Engineers usually need to use a standard chip (e.g. a golden sample) to adjust and calibrate the test equipment. At this time, this embodiment will place the load board 12 on the body 10 so that the body 10 of the chip carrier 1 and the load board 12 can be combined. Specifically, the load board 12 can be defined with a first surface 12a and a second surface 12b on opposite sides. The first surface 12a of the load board 12 can define a second chip position 120 (the area enclosed by the dashed line). Although only one second chip position 120 is indicated in FIG. 3, this embodiment is not limited thereto. For example, the first surface 12a of the load board 12 can also define multiple second chip positions 120. The second chip position 120 refers to a position on the first surface 12a of the load board 12 where a standard chip GS is placed, and each second chip position 120 is used to accommodate one corresponding standard chip GS. It is worth mentioning that unlike the chip under test which is not preset within the first chip position 102, the standard chip GS is preset within the second chip position 120 so that the load board 12 can be regarded as a plug-in that changes the chip carrier 1 into a standard part. When the body 10 and the load board 12 are combined, the chip carrier 1 can be used as an integrated standard part.

When the body 10 and the load board 12 are combined, that is, when the load board 12 is located in the test area 100, the back side (the second surface 12b) of the load board 12 directly contacts the test area 100. In one example, the second chip position 120 in the first surface 12a is also roughly located at the center of the load board 12, and the second chip position 120 can roughly overlap, in the vertical direction, with the first chip position 102. Here, the thickness of the load board 12 can be approximately equal to the depth of the test area 100 recessed into the upper surface 10a so that after the load board 12 is placed in the test area 100, there is basically no difference between the load board 12 and the surrounding upper surface 10a. In practice, the load board 12 can be detachably combined with the test area 100 of the body 10. This embodiment does not limit how to combine the load board 12 with the body 10. For example, the load board 12 can be locked, snapped, or glued in the test area 100, or simply just placed in the test area 100.

Similar to the chip under test, the standard chip GS can also be a light emitting chip in side-emission configuration, and the two electrodes of the standard chip GS are also located on the top and bottom. A conductive block 126 can be disposed within the load board 12. The conductive block 126 is located below the second chip position 120, and exposed on both the first surface 12a and the second surface 12b. In one example, the conductive block 126 can be composed of one or more conductive pillars embedded in the load board 12 and penetrated through the load board 12 to expose on both the first surface 12a and the second surface 12b. This embodiment does not limit the shape of the conductive pillar. For example, it can be a circular or rectangular pillar. At this time, the electrode (e.g., cathode) on the lower side of the standard chip GS is electrically connected to the body 10 via the conductive block 126 and then electrically connected to the test equipment via the body 10. Unlike the electrode on the top of the chip under test that may directly contact the probe of the test equipment, it is necessary to avoid direct contact between the probe and the electrode on the top of the standard chip GS. The reason is that if the electrode on the top (e.g., anode) of the standard chip GS frequently contacts the probe, it is likely to be worn or damaged by the probe, that reduces the accuracy of the standard chip GS. In practice, the electrode on the top of the standard chip GS can be connected to a first electrode pad 122 by wire bonding and then connected to a protective conductor 124 located above the standard chip GS via the first electrode pad 122.

As shown in FIG. 3, it can be seen that below the protective conductor 124, there can be the standard chip GS, the first electrode pad 122, and a metal wire connecting the standard chip GS and the first electrode pad 122. In order to maintain the accuracy of the standard part, one of the functions of the protective conductor 124 is to protect the relatively fragile structure below it. That is to say, in the vertical direction, the protective conductor 124 will shield the standard chip GS. However, the protective conductor 124 should also avoid contacting the standard chip GS so as not to be directly stacked on top of it. In other words, the protective conductor 124 can be regarded as a cantilever structure, which still maintains a distance from the standard chip GS, the first electrode pad 122, and the metal wire connecting the standard chip GS and the first electrode pad 122 in the vertical direction.

In another example, another function of the protective conductor 124 is to allow direct contact with the probe. Considering that the probe of the test equipment is originally designed to contact the electrode on the top of the chip under test vertically, in order not to change the original operation of the probe of the test equipment, the protective conductor 124 in this embodiment can be contacted by the probe of the test equipment vertically. In practice, assuming that the horizontal position of the probe has been aligned with the first chip position 102 (prepare to contact the chip under test), it is only necessary to move the probe vertically and combine the load board 12 with the body 10 if the calibration process needs to be performed. Since the second chip position 120 roughly overlaps with the first chip position 102 vertically, when the probe descends, it should contact, firstly, the protective conductor 124 that shields the standard chip GS in the vertical direction. Person having ordinary skill in the art can understand that since it is easy for the probe to move vertically, the protective conductor 124 slightly higher than the standard chip GS will not affect the operation of the probe and make it easy for the probe to contact protective conductor 124 downward. Moreover, when the probe contacts the protective conductor 124, it can also be electrically connected to the electrode on the top of the standard chip GS via the protective conductor 124 and the first electrode pad 122. Therefore, when the chip carrier 1 has the load board 12 disposed on the body 10, the test equipment can regard the chip carrier 1 as the standard part and perform adjustments or calibrations accordingly.

In another example, one or more extended electrode pads 128 can be provided on the first surface 12a of the load board 12. Although two extended electrode pads 128 are shown in FIG. 3, the number of the extended electrode pads 128 is not limited in this embodiment. In addition, the two extended electrode pads 128 can be electrically connected to the electrodes on the same side of the standard chip GS or to the electrodes on different sides of the standard chip GS. That is to say, assuming that one of the extended electrode pads 128 is electrically connected to the electrode on the top of the standard chip GS, then protective conductor 124 should be electrically connected to the first electrode pad 122 and the extended electrode pad 128 at the same time. The function of the extended electrode pad 128 is to provide a place for the probe to contact vertically so that the probe can electrically connect to the electrode on the standard chip GS via the extended electrode pad 128. However, person having ordinary skill in the art can understand that the extended electrode pad 128 is not a necessary component. For example, if there is no extended electrode pad 128, the probe can directly contact the protective conductor 124 or the body 10 to achieve similar effects.

On the other hand, body 10 can have one or more identification patterns, which are not limited to text, patterns, or barcodes. For example, this embodiment shows an identification pattern 104 and an identification pattern 106. The identification pattern 104 can be a two-dimensional barcode, while the identification pattern 106 can be text. However, regardless of the type of identification patterns, person having ordinary skill in the art should understand that the identification pattern should be used to identify the chip carrier 1. For example, the identification pattern can be used to indicate whether the chip carrier 1 carries the chip under test or the standard chip GS, or to indicate the specifications and models of the chip under test or the standard chip GS.

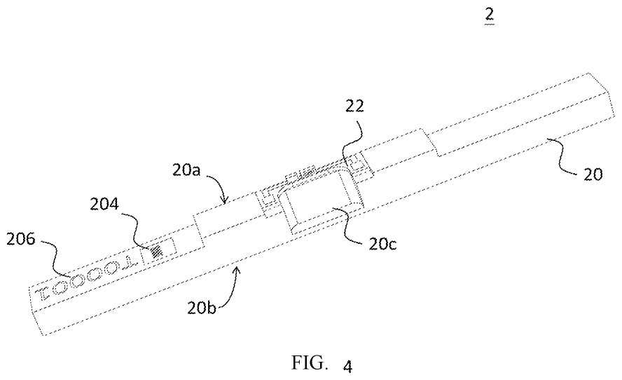

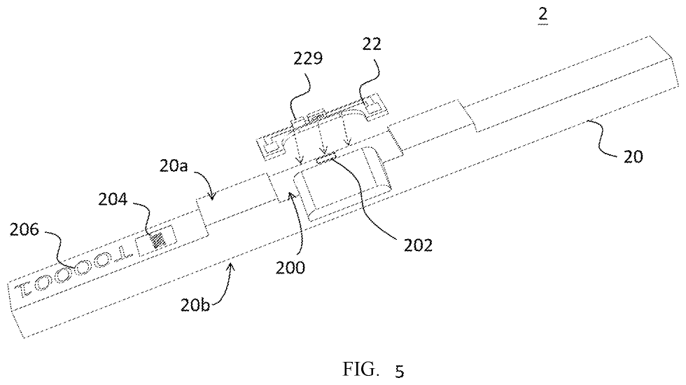

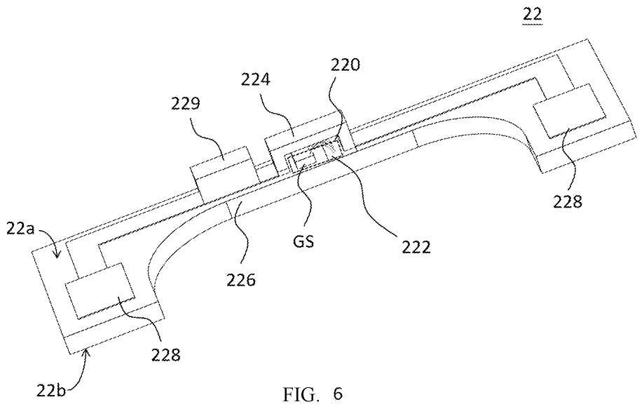

In addition, the load board 12 of the chip carrier 1 can also integrate other functional units. Please refer to FIG. 4, FIG. 5 and FIG. 6 together, FIG. 4 illustrates a three-dimensional schematic diagram of a chip carrier according to another embodiment of the present invention. FIG. 5 illustrates an exploded view of the chip carrier according to another embodiment of the present invention. FIG. 6 illustrates a three-dimensional schematic diagram of a load board according to another embodiment of the present invention. As shown in the figures, similar to the previous embodiment, the chip carrier 2 also has a detachable body 20 and a load board 22, and the body 20 can define an upper surface 20a and a lower surface 20b on opposite sides. The upper surface 20a can define a test area 200, which can be roughly located at the center of upper surface 20a, and the test area 200 can also be slightly concave on upper surface 20a. In addition, in this embodiment, a position for placing a chip can also be defined in test area 200, such as a first chip position 202 for accommodating a corresponding chip under test. When the body 20 and the load board 22 are combined together, i.e., when the load board 22 is located in the test area 200, the back side (the second surface 22b) of the load board 22 will directly contact the test area 200. In one example, the second chip position 220 in the first surface 22a is also roughly located at the center of the load board 22, and the second chip position 220 can roughly overlap the first chip position 202 in the vertical direction.

In addition, a conductive block 226 can also be disposed within the load board 22. The conductive block 226 is located below the second chip position 220 and exposed on the first surface 22a and the second surface 22b. At this time, the electrode, on the bottom, of the standard chip GS is electrically connected to the body 20 via the conductive block 226, and then electrically connected to the test equipment via the body 20. The electrode on the top of the standard chip GS can be connected to the first electrode pad 222 via wire bonding, and then connected to the protective conductor 224 located above the standard chip GS. One or more extended electrode pads 228 can also be provided on the first surface 22a of the load board 22. The two extended electrode pads 228 shown in the figures can be electrically connected to the electrodes on the same surface of the standard chip GS, or can be electrically connected to the electrodes on different surfaces of the standard chip GS. On the other hand, the body 20 can also have one or more identification patterns. The identification pattern is not limited to text, patterns, or barcodes. For example, an identification pattern 204 and an identification pattern 206 are marked in this embodiment. The details of the above components are generally the same as those in the previous embodiment and are not described here.

Unlike the previous embodiment, a temperature control unit 229 is provided on the first surface 22b of the load board 22. The temperature control unit 229 is used to control the temperature of the load board 22, especially to control an ambient temperature around the second chip position 222. Since the load board 22 with the standard chip GS is used as a standard part, especially when the standard chip GS needs to be controlled in a stable operating environment, the temperature control unit 229 is required to maintain the ambient temperature around the second chip position 222 with the standard chip GS. In practice, the temperature control unit 229 can be a temperature control chip, and the location of the temperature control unit 229 can be as close as possible to the standard chip GS. In the example of FIG. 6, the temperature control unit 229 can be directly placed on the metal line of the extended electrode pad 228. The reason is that the metal line of the extended electrode pad 228 is a conductor and can conduct heat more quickly. The temperature control unit 229 can easily reach thermal equilibrium with the second chip position 222 through the metal line to adjust the ambient temperature around the second chip position 222. For example, the temperature control unit 229 can control the ambient temperature around the second chip position 222 between −40° C. and +125° C. Of course, person having ordinary skill in the art can choose the specifications of the temperature control unit 229 to change the range of controlled temperature.

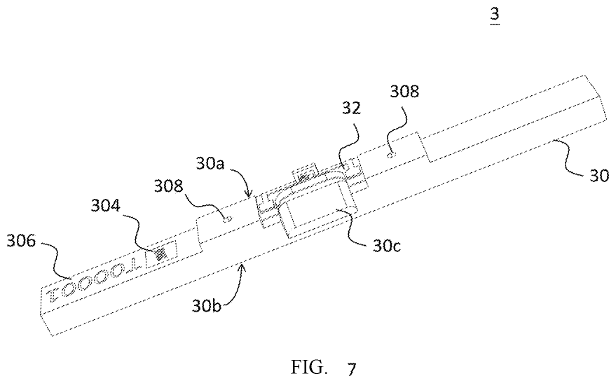

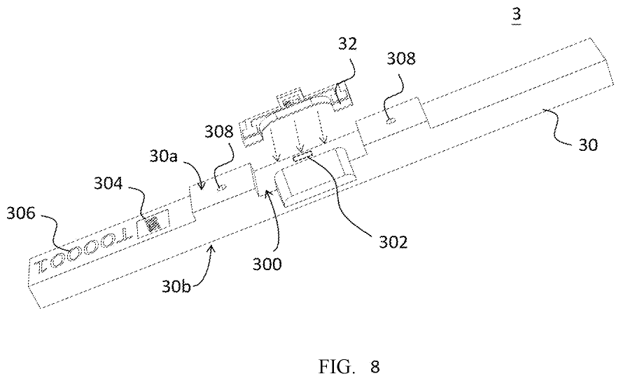

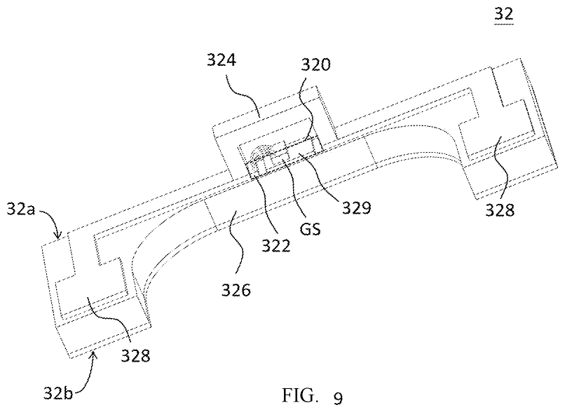

Furthermore, unlike the previous embodiment that the electrode (e.g., cathode) on the bottom of the standard chip GS is directly provided on the conductive block 226 of the load board 22a. The electrode on the bottom of the standard chip GS may also be provided on an electrode pad. Please also refer to FIG. 7 to FIG. 9. FIG. 7 illustrates a three-dimensional schematic diagram of a chip carrier according to yet another embodiment of the present invention. FIG. 8 illustrates an exploded view of the chip carrier according to yet another embodiment of the present invention. FIG. 9 illustrates a three-dimensional schematic diagram of a load board according to yet another embodiment of the present invention. As shown in the figures, similar to the first embodiment shown in FIG. 1 to FIG. 3, the chip carrier 3 here also has a detachable body 30 and a load board 32, and the body 30 can define an upper surface 30a and a lower surface 30b on opposite sides. The upper surface 30a can define a test area 300, which can be roughly located at the center of the upper surface 30a and can also be slightly recessed into the upper surface 30a. In addition, in this embodiment, a position for placing a chip can also be defined in the test area 300, such as a first chip position 302 for accommodating a corresponding chip under test. When the body 30 and the load board 32 are combined together, i.e., when the load board 32 is located in the test area 300, the back side (the second surface 32b) of the load board 32 will directly contact the test area 300. In one example, the second chip position 320 in the first surface 32a is also roughly located at the center of the load board 32 and can roughly overlap the first chip position 302 in vertical direction. In addition, a conductive block 326 may also be disposed within the load board 32, one or more extended electrode pads 328 may also be provided on the first surface 32a of the load board 32, and the body 30 may also have one or more identification patterns such as an identification pattern 204 and an identification pattern 206. The details of these components are generally similar to those in the previous embodiment and are not described here.

Different from the first embodiment shown in FIG. 1 to FIG. 3, the upper surface 30a of the body 30 in this embodiment has one or more grooves 308. Although FIG. 8 shows two grooves 308, this embodiment does not limit the number of the groove. In the example of FIG. 8, the two grooves 308 are provided on opposite sides of the test area 300 and the grooves 308 do not penetrate the body 30 but instead opens out into a recessed structure on the upper surface 30a. In one example, one function of the grooves 308 may be to help the test equipment align with the chip carrier 3. For example, the test equipment needs to align with the chip carrier 3 before driving the probe to contact the protective conductor 324 from above. Before the probe descends, the groove 308 can be aligned with a locating member of the test equipment. When the locating member is inserted into the groove 308, it can be determined that whether the test equipment has aligned with the chip carrier 3. In another example, one function of the groove 308 may be to help transport the chip carrier 3. When transporting other chip carriers, a suction nozzle may first suck onto a flat portion of the upper surface and then vacuum to lift the entire chip carrier. Different from the previous embodiment, in order to improve vacuum efficiency in this embodiment, the suction nozzle can be aligned with the groove 308 of the chip carrier 3 so that the groove 308 can form an air chamber that reserves some space, and helps the suction nozzle suck onto the chip carrier 3.

Different from the first embodiment shown in FIG. 1 to FIG. 3, although the top electrodes of the standard chip GS can still be connected to the first electrode pad 322 on the load board 32 via wire bonding, the bottom electrodes of the standard chip GS are not directly placed on the conductive block 326. In this embodiment, a second electrode pad 329 is provided on the first surface 32a and disposed within the second chip position 320 and connected to the conductive block 326. Compared with the first embodiment, since the standard chip GS in this embodiment is raised by the second electrode pad 329, the protective conductor 324 should also be higher than the protective conductor 124 shown in FIG. 3. That is to say, the protective conductor 324 still covers the standard chip GS and does not directly stack on it. Based on the above, person having ordinary skill in the art can understand that this embodiment does not limit the size of the protective conductor 324. For example, this embodiment does not limit the height or shielding area of the protective conductor 324 in the vertical direction.

On the other hand, FIG. 9 shows that the first electrode pad 322, the second electrode pad 329, and the extended electrode pad 328 are actually the same metal layer. In one example, the metal layer is formed based on the same process, so that the thickness of the first electrode pad 322, the second electrode pad 329, and the extended electrode pad 328 are roughly the same. This embodiment does not limit the thickness of the metal layer (i.e., the first electrode pad 322, the second electrode pad 329, and the extended electrode pad 328). In practice, the protective conductor 324 can be made of metal material and has a symmetric and inverted U-shaped structure. The protective conductor 324 can be overlaid on the metal layer to shield an area below the inverted U-shaped structure.

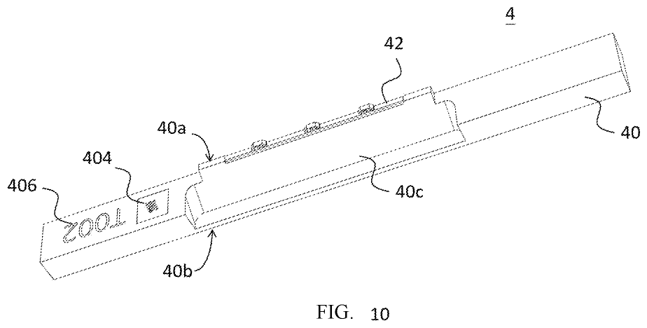

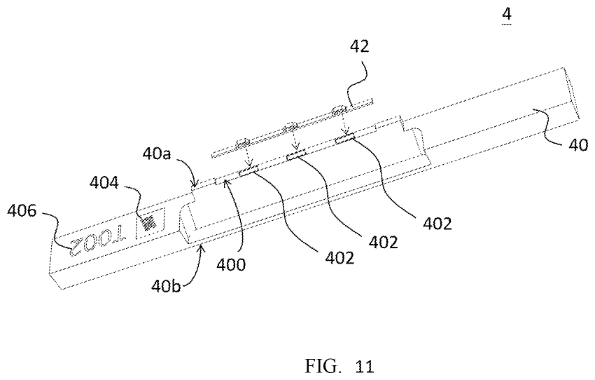

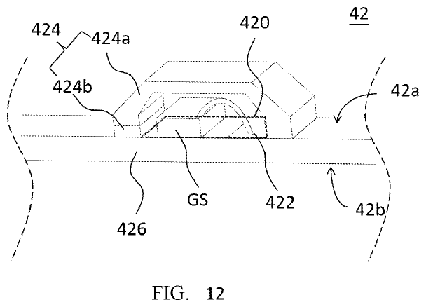

In one example, the protective conductor can also be an asymmetric and inverted U-shaped structure, and there can be multiple protective conductors on the load board. Please also refer to FIG. 10 to FIG. 12. FIG. 10 illustrates a three-dimensional schematic diagram of a chip carrier according to still another embodiment of the present invention. FIG. 11 illustrates an exploded view of the chip carrier according to still another embodiment of the present invention. FIG. 12 illustrates a three-dimensional schematic diagram of part of a load board according to still another embodiment of the present invention. As shown in figures, similar to the first embodiment shown in FIG. 1 to FIG. 3, the chip carrier 4 also has a detachable body 40 and a load board 42, and the body 40 can define an upper surface 40a and a lower surface 40b on opposite sides. The upper surface 40a can define a test area 400, which can be roughly located at the center of the upper surface 40a and can be slightly recessed into the upper surface 40a. In addition, when the body 40 and the load board 42 are combined together, i.e., when the load board 42 is located in the test area 400, the back side (the second surface 42b) of the load board 42 will directly contact the test area 400. Furthermore, the conductive block 426 can also be disposed within the load board 42, and the body 40 can also have one or more identification patterns, such as an identification pattern 404 and an identification pattern 406. The details of these components are generally the same as those in the previous embodiment and are not described here.

Unlike the first embodiment illustrated in FIG. 1 to FIG. 3, in this embodiment, a plurality of positions for placing chips are defined in the test area 400, such as a plurality of first chip positions 402, and each first chip position 402 can be used to accommodate a corresponding chip under test. In one example, the plurality of the first chip positions 402 can be arranged at equal intervals in the test area 400. The first surface 42a of the load board 42 can also has a plurality of second chip positions 420 correspondingly. In the vertical direction, each second chip position 420 and the corresponding first chip position 402 are roughly overlapped. In addition, although the load board 42 of this embodiment also has an inverted U-shaped protective conductor 424, it can be seen that the appearance of the protective conductor 424 is different from that of the above-described embodiment. For example, unlike the protective conductor 124 illustrated in FIG. 3 having a right angle at a bend, the protective conductor 424 has a chamfered design at the bend. On the other hand, the protective conductor 424 of this embodiment is not symmetrical. Specifically, the protective conductor 424 is composed of a protective cantilever 424a and an elastic block 424b. Structurally, the protective cantilever 424a shields the standard chip GS disposed in the second chip position 420 in the vertical direction, and the elastic block 424b is located between the protective cantilever 424a and the first surface 42a. Moreover, it can be seen from FIG. 12 that the protective cantilever 424a is thicker near the first surface 42a and thinner away from it, which indicates that the protective cantilever 424a itself has structural elasticity.

In one example, one end of the protective cantilever 424a is directly disposed within the first surface 42a, and the elastic block 424b supports the other end of the protective cantilever 424a. Since the elastic block 424b is made of a material having elasticity, when the probe contacts the protective cantilever 424a from above, the stress applied to the protective cantilever 424a by the probe can be absorbed by the elastic block 424b, thereby more effectively avoiding damage to the protective cantilever 424a caused by stress from the probe. The position of the elastic block 424b is not limited in this embodiment, and the elastic block 424b should be able to absorb at least a portion of the stress applied to the protective cantilever 424a by the probe as long as the protective conductor 424 is composed of the protective cantilever 424a and the elastic block 424b. In addition, an extended electrode pad may not be provided on the first surface 42a of the load board 42 of this embodiment. As described above, electrodes (e.g., cathodes) on multiple lower surfaces of the standard chips GS can be electrically connected to a common negative terminal via a conductive block 426. Since the body 40 is made of a conductive material, the probe can electrically connect to electrodes on the bottom of the standard chips GS by contacting the body 40 without necessarily requiring an extended electrode pad. In an example, another probe can contact a corresponding protective conductor 424 to drive standard chips GS.

In summary, the chip carrier provided by the present invention has a detachable load board that can carry a standard chip. When the load board is located in the body, the combination of the body and the load board can be regarded as a standard part. When the load board is not located in the body, the body can carry a chip under test which can reduce the repeated suction and release of the chip, thereby reducing the chance of the chip being damaged.

What is claimed is:

1. A chip carrier, for selectively carrying a chip under test or a standard chip, comprising:
a body defining a test area; and
a load board detachably located in the test area;
wherein the test area is located on an upper surface of the body, and a first chip position is defined in the test area;
wherein a second chip position is defined in the load board, and the standard chip is disposed within the second chip position;
wherein when the load board is located in the test area, the load board covers the first chip position, and the chip under test is not disposed within the first chip position;
wherein when the chip under test is disposed within the first chip position, the load board is not located in the test area.

2. The chip carrier according to claim 1, wherein the load board defines a first surface and a second surface, opposite to the first surface, the second chip position is located on the first surface, and the second surface contacts the first chip position when the load board is located in the test area.

3. The chip carrier according to claim 2, wherein the first surface is further provided with a first electrode pad, the first electrode pad is connected to a protective conductor, the protective conductor shields the standard chip in a vertical direction, and the standard chip is a light emitting chip in side-emission configuration.

4. The chip carrier according to claim 3, wherein a conductive block is disposed within the load board, the conductive block is exposed at the second chip position on the first surface, and the conductive block is exposed on the second surface.

5. The chip carrier according to claim 4, wherein the protective conductor is composed of a protective cantilever and an elastic block, the protective cantilever shields the standard chip in the vertical direction, the elastic block is located between the protective cantilever and the first surface, and the elastic block absorbs stress applied to the protective cantilever.

6. The chip carrier according to claim 3, wherein the first surface is provided with a second electrode pad, the second electrode pad is located in the second chip position and connected to a conductive block, the conductive block is disposed within the load board and exposed on the second surface.

7. The chip carrier according to claim 3, wherein the first surface is further provided with an extended electrode pad, and the protective conductor is electrically connected to the first electrode pad and the extended electrode pad.

8. The chip carrier according to claim 1, wherein the test area is recessed into the upper surface, the load board is placed in the test area, and the body is made of conductive material.

9. The chip carrier according to claim 1, wherein the load board has a temperature control unit, and the temperature control unit is used to control an ambient temperature around the second chip position.

10. The chip carrier according to claim 1, wherein the body is provided with an identification pattern, and the identification pattern is used to identify the chip carrier.
